(19) United States
(12) Patent Application Publication
(10) Pub. No.: US 2017/0092861 A1
(43) Pub. Date: Mar. 30, 2017

(54) A METAL MASK PLATE AND AN ORGANIC ELECTROLUMINESCENT DISPLAY DEVICE MANUFACTURED USING THE SAME

(71) Applicants: Boe Technology Group Co., Ltd., Beijing (CN); Ordos Yuanshen Optoelectronics Co., Ltd., Inner Mongolia (CN)

(72) Inventor: Zhiming Lin, Beijing (CN)

(21) Appl. No.: 14/905,397

(22) PCT Filed: Jul. 31, 2015
(86) PCT No.: PCT/CN2015/085758

§ 371 Date: Jan. 15, 2016

(30) Foreign Application Priority Data
Mar. 13, 2015 (CN) 201510112760.6

(51) Int. Cl. H01L 51/00; B05D 1/32; B05D 1/00; H01L 51/50

(52) U.S. Cl. CPC H01L 51/0011; H01L 51/50; B05D 1/32; B05D 1/60

(57) ABSTRACT

A metal mask plate comprises: a substrate, a first area arranged on the substrate and second areas located at left and right sides of the first area respectively; the first area being provided with a plurality of first strip slits extending along a column direction and being parallel to each other, each of the second areas being provided with at least three second strip slits parallel to the first strip slits; wherein, at least two of the following three conditions are met: a width of the second strip slit is less than a width of the first strip slit; a distance between adjacent second strip slits in a same second area is less than a distance between adjacent first strip slits; a width of a side area is narrowed.

### RELATED APPLICATIONS

The present application is the U.S. national phase entry of PCT/CN15/08578, with an international filing date of Jul. 31, 2015, which claims the benefit of Chinese Patent Application No. 201510112760.6, filed on Mar. 13, 2015, the entire disclosures of which are incorporated herein by reference.

### FIELD OF THE DISCLOSURE

The present disclosure relates to the field of display technology, particularly to a metal mask plate and an organic electroluminescent display device manufactured using the same.

### BACKGROUND OF THE DISCLOSURE

At present, the organic electroluminescent display (OLED) has gradually become the mainstream of the display field by right of its excellent performance of low power consumption, high color saturation, wide visual angle, small thickness, and flexibility, etc.

The evaporation technology is the critical technology in the process of manufacturing an OLED display screen. The OLED mainly adopts light emitting layers of the three colors of red, green, and blue to achieve a relatively good luminous efficiency, while the evaporation technology is mainly applied in the film forming process of organic light emitting materials of the light emitting layers of the three colors of red, green, blue. In the film forming process, a fine metal mask (FMM) is mainly used for performing evaporation, and the organic light emitting materials of the three colors of red, green, and blue are plated side by side in each pixel unit of the OLED panel respectively, one color every time, so as to form pixel units in which the organic light emitting materials of the three colors of red, green, and blue are deposited respectively. In the evaporation process of the OLED, a magnetic separator is generally required to adsorb the whole metal mask plate so as to improve sag of the metal mask plate. As shown in FIG. 1a, the metal mask plate consisting of strip slits 001, in the process of moving upwards adsorbed by the magnetic separator 002, is easily subjected to the influence of the magnetic force of the magnetic separator 002, since the shortest distance m between the strip slit in the metal mask plate and the side frame 003 parallel to it is generally greater than the distance n between adjacent strip slits 001. In that case, the generated magnetic force is large, such that a plurality of strip slits 001 that are close to the side frame 003 are deformed, which is unfavorable for manufacturing a high resolution OLED display screen. Therefore, as shown in FIG. 1b, at least three strip slits adjacent to the side frame need to be arranged in the corresponding non-display area A, so that the strip slits in the corresponding display area B would not be deformed. However, the width of the frame of the OLED display screen is thus limited.

Therefore, to reduce the frame of the OLED display screen so as to realize narrow frame while meeting the condition that the strip slits in the corresponding display area will not be deformed under the effect of the magnetic field is a technical problem that needs to be solved by the skilled person in the art urgently.

### SUMMARY OF THE DISCLOSURE

In view of this, the embodiment of the present disclosure provides a metal mask plate and an organic electroluminescent display device manufactured using the same, which enables the second areas to occupy a relatively small area so as to realize narrow frame in space.

One embodiment of the present disclosure provides a metal mask plate, comprising: a substrate, a first area arranged on the substrate for forming display images and second areas located at left and right sides of the first area respectively; the first area being provided with a plurality of first strip slits extending along the column direction and being parallel to each other with equal intervals, each of the second areas being provided with at least three second strip slits parallel to the first strip slits; wherein,

at least two of the following three conditions are met:

condition one: a width of the second strip slit is less than a width of the first strip slit;

condition two: a distance between adjacent second strip slits in a same second area is less than a distance between adjacent first strip slits;

condition three: a width of a side area is narrowed, the side area being an area between the second strip slit in the second area closest to a side frame of the metal mask plate and the side frame, the side frame being a frame parallel to the extending direction of the second strip slit.

In a possible implementing mode, in the above metal mask plate provided by one embodiment of the present disclosure, when condition one and condition two are met simultaneously, the width of each of the second strip slits is the same.

In a possible implementation, in the above metal mask plate provided by one embodiment of the present disclosure, the distance between adjacent second strip slits in the same second area is the same; or, the distance between adjacent second strip slits in the same second area increases or decreases successively along a direction that the side area points to the first area.

In a possible implementing mode, in the above metal mask plate provided by one embodiment of the present disclosure, when condition one and condition three are met simultaneously, the width of each of the second strip slits is the same; or,

the width of the second strip slits in the same second area increases successively along a direction that the side area points to the first area.

In a possible implementation, in the above metal mask plate provided by one embodiment of the present disclosure, when the condition two and the condition three are met simultaneously, the distance between adjacent second strip slits in the same second area is the same; or,

the distance between adjacent second strip slits in the same second area increases successively along a direction that the side area points to the first area.

In a possible implementation, in the above metal mask plate provided by one embodiment of the present disclosure, when condition one, condition two and condition three are met simultaneously, the width of each of the second strip slits is the same; and

the distance between adjacent second strip slits in the same second area is the same; or, the distance between adjacent second strip slits in the same second area increases successively along a direction that the side area points to the first area.

In a possible implementation, in the above metal mask plate provided by one embodiment of the present disclosure, when condition one, condition two, and condition three are met simultaneously, the width of each of the second strip slits in the same second area increases successively along a direction that the side area points to the first area; and

the distance between adjacent second strip slits in the same second area is the same; or, the distance between adjacent second strip slits in the same second area increases successively along the direction that the side area points to the first area.

In a possible implementation, in the above metal mask plate provided by one embodiment of the present disclosure, when the condition one is met, the width of the second strip slit is greater than 5 μm and less than 35 μm.

In a possible implementing mode, in the above metal mask plate provided by one embodiment of the present disclosure, when the condition two is met, the distance between adjacent second strip slits in the same second area is less than 70 μm.

In a possible implementing mode, in the above metal mask plate provided by one embodiment of the present disclosure, when the condition three is met, the width of the side area is less than 2.45 mm.

Another embodiment of the present disclosure further provides an organic electroluminescent display device manufactured using the above metal mask plate provided by one embodiment of the present disclosure.

The beneficial effect of the embodiment of the present disclosure includes:

The embodiment of the present disclosure provides a metal mask plate and an organic electroluminescent display device manufactured using the same, the metal mask plate comprising: a substrate, a first area arranged on the substrate for forming display images and second areas located at left and right sides of the first area respectively. The first area is provided with a plurality of first strip slits extending along the column direction and being parallel to each other with equal intervals, each of the second areas being provided with at least three second strip slits parallel to the first strip slits. At least two of the following three conditions are met: condition one: a width of the second strip slit is less than a width of the first strip slit; condition two: a distance between adjacent second strip slits in a same second area is less than a distance between adjacent first strip slits; and/or condition three: a width of a side area is narrowed, the side area being an area between the second strip slit in the second area closest to a side frame of the metal mask plate and the side frame, the side frame being a frame parallel to the extending direction of the second strip slit. By adjusting the width of the second strip slit, the distance between adjacent second strip slits in the same second area and the width of the side area. When at least two of the above conditions are met, and on the basis that the first strip slits in the first area would not be deformed due to force balance under the effect of the magnetic field, relative to the prior art, not only the influence of the magnetic field to the second strip slits can be released, but also the second areas can be made to occupy a relatively small area, so as to realize narrow frame in space.

### BRIEF DESCRIPTION OF THE DRAWINGS

FIG. 1a is a structural schematic view of a metal mask plate combined with a magnetic separator in the prior art;

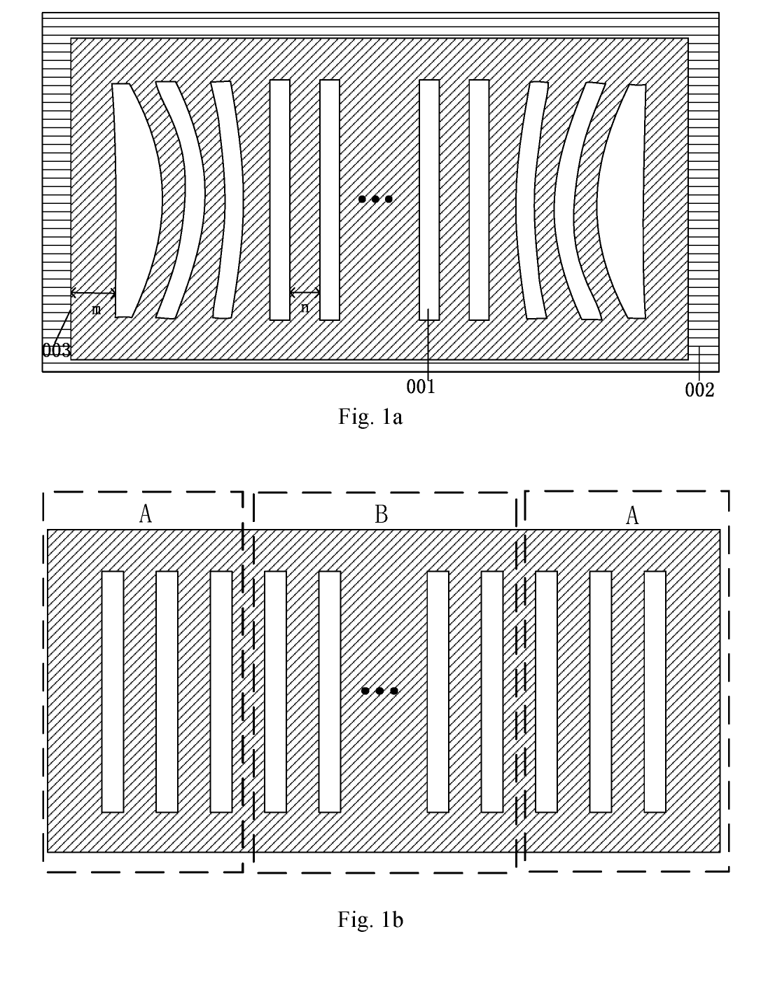

FIG. 1b is a structural schematic view of a metal mask plate in the prior art;

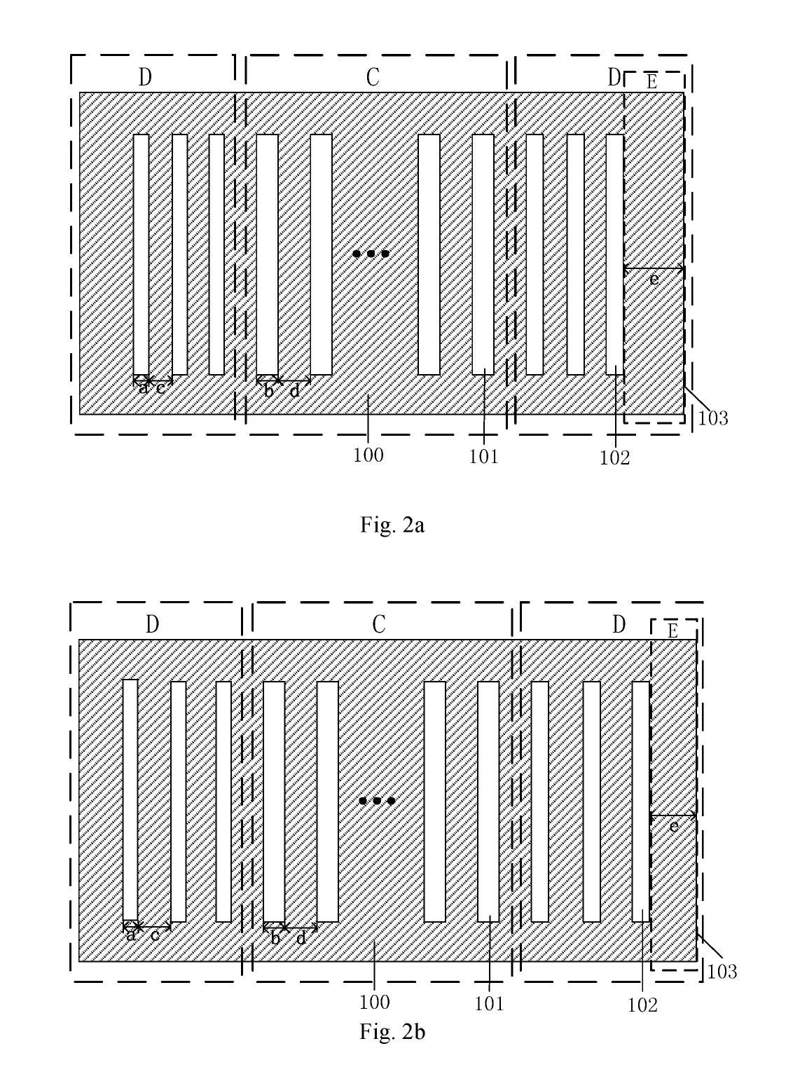

FIG. 2a to FIG. 2d are structural schematic views of metal mask plates provided by the embodiments of the present disclosure respectively;

FIG. 3a is a structural schematic view of the metal mask plate as shown in FIG. 2d combined with a magnetic separator;

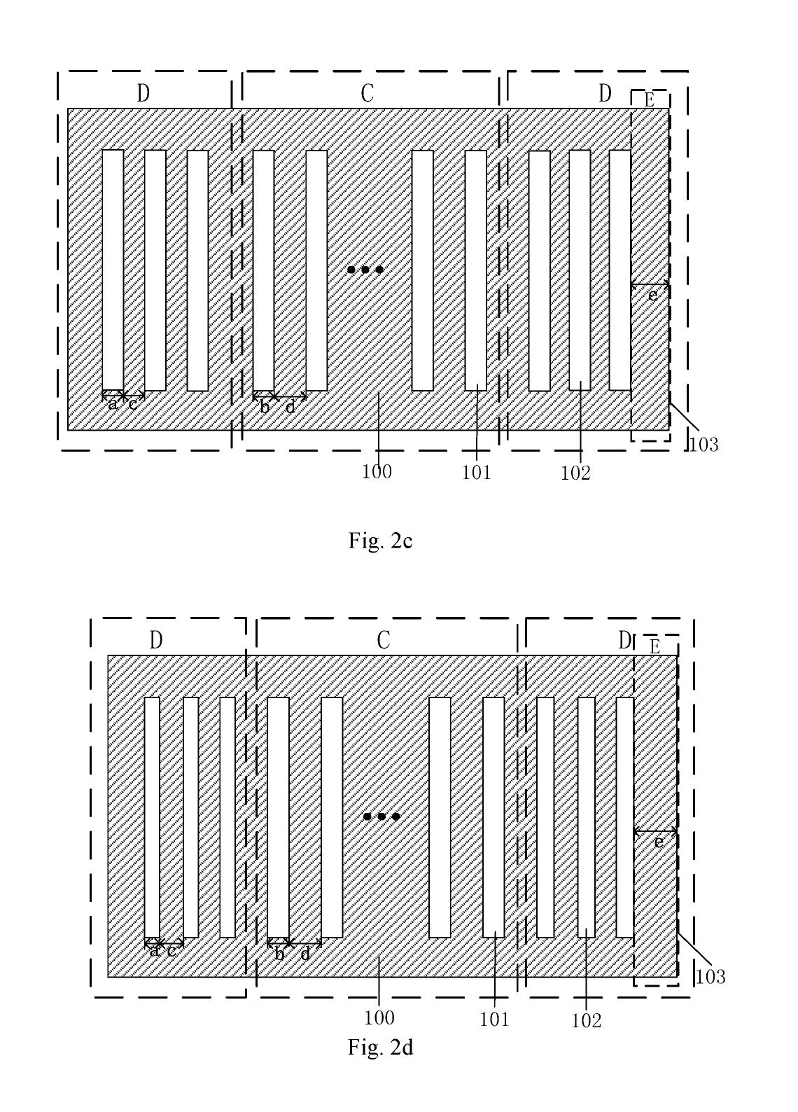

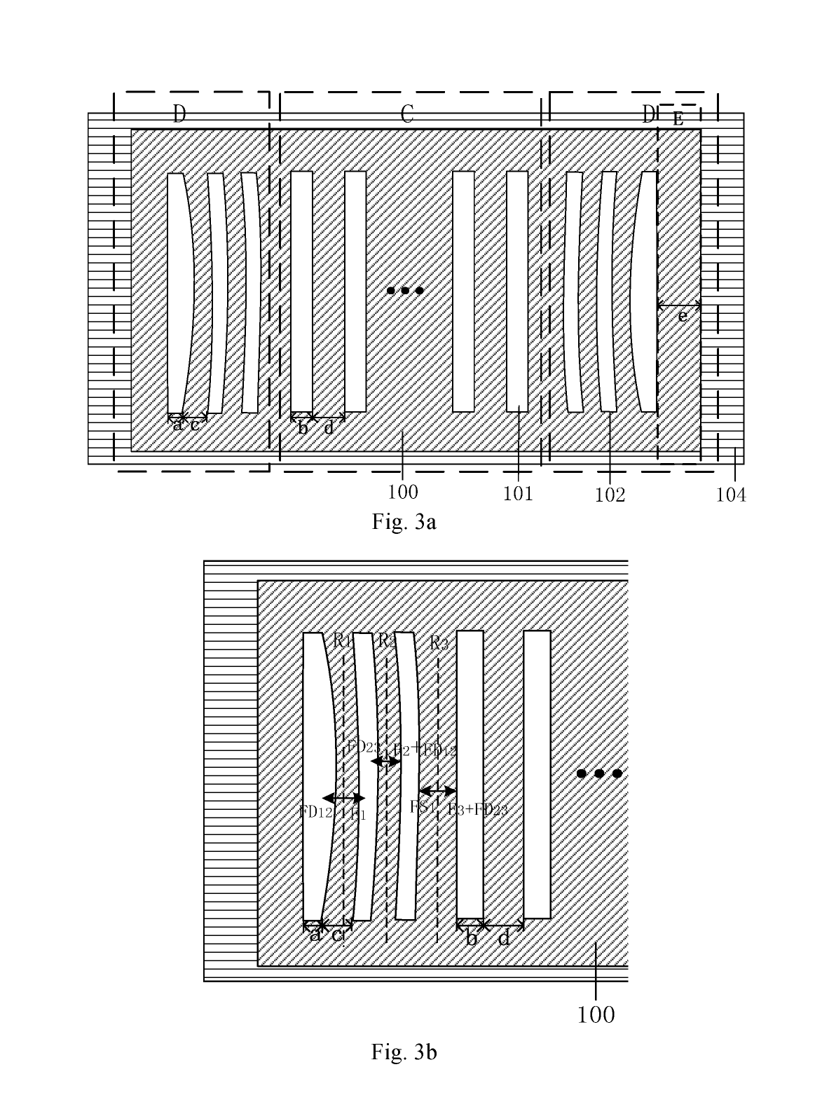

FIG. 2b is a partial enlarged view of FIG. 3a.

### DETAILED DESCRIPTION OF THE DISCLOSURE

Next, the specific implementing modes of the metal mask plate and the organic electroluminescent display device manufactured using the same provided by the embodiment of the present disclosure will be explained in detail with reference to the drawings.

Herein, the drawings all adopt simplified forms and use non precise proportions, which only aim to explaining the contents of the present disclosure schematically.

One embodiment of the present disclosure provides a metal mask plate, as shown in FIG. 2a to FIG. 2d, the metal mask plate comprising: a substrate 100, a first area C arranged on the substrate 100 for forming display images and second areas D located at left and right sides of the first area C respectively; the first area C being provided with a plurality of first strip slits 101 extending along the column direction and being parallel to each other with equal intervals, each of the second areas D being provided with at least three second strip slits 102 parallel to the first strip slits 101; wherein,

at least two of the following three conditions are met:

condition one: a width a of the second strip slit 102 is less than a width b of the first strip slit 101;

condition two: a distance c between adjacent second strip slits 102 in a same second area D is less than a distance d between adjacent first strip slits 101; and/or

condition three: a width of a side area E is narrowed, the side area E being an area between the second strip slit 102 in the second area D closest to a side frame 103 of the metal mask plate and the side frame 103, the side frame 103 being a frame parallel to the extending direction of the second strip slit 102.

In the above metal mask plate provided by one embodiment of the present disclosure, by adjusting the width a of the second strip slit 102, the distance c between adjacent second strip slits 102 in the same second area D and the width e of the side area E, when at least two of the above conditions are met, on the basis that the first strip slits 101 in the first area C would not be deformed due to force balance under the effect of the magnetic field, relative to the prior art, not only the influence of the magnetic field to the second strip slits 102 can be released, but also the second areas D can be made to occupy a relatively small area, so as to realize narrow frame in space.

In specific implementation, in the above metal mask plate provided by one embodiment of the present disclosure, as shown in FIG. 2a, when the condition one and the condition two are met simultaneously, i.e., the width a of the second strip slit 102 is less than the width b of the first strip slit 101, when the distance c between adjacent second strip slits 102 in the same second area D is less than the distance d between adjacent first strip slits 101, and the width e of the side area E is constant, the width a of each of the second strip slits 102 may be the same (i.e., when the width of each of the second strip slits 102 is adjusted, the width of each of the second strip slits 102 can be reduced by the same quantitative value).

Further, in specific implementations, in the above metal mask plate provided by one embodiment of the present disclosure, when the condition one and the condition two are met simultaneously and the width a of each of the second strip slits 102 is the same, the distance c between adjacent second strip slits 102 in the same second area D can also be the same, (i.e., when the distance between adjacent second strip slits 102 in the same second area D is adjusted, the distance between adjacent second strip slits 102 in the same second area D can be reduced by the same quantitative value). Alternatively, the distance c between adjacent second strip slits 102 in the same second area D can increase or decrease successively along a direction that the side area E points to the first area C, (i.e., when the distance between adjacent second strip slits 102 in the same second area D, the distance between adjacent second strip slits 102 in the same second area D along the direction that the side area E points to the first area C is c₁, c₂, c₃ respectively, and when c₁, c₂, c₃ are adjusted, c₁ can be reduced by 3 μm, c₂ can be reduced by 2 μm, c₃ can be reduced by 1 μm, or c₁ can be reduced by 1 μm, c₂ can be reduced by 2 μm, and c₃ can be reduced by 3 μm).

In specific implementation, in the above metal mask plate provided by one embodiment of the present disclosure, as shown in FIG. 2b, when the condition one and the condition three are met simultaneously, i.e., when the width a of the second strip slit 102 is less than the width b of the first strip slit 101, the distance e of the side area E is narrowed, and the distance c between adjacent second strip slits 102 in the same second area D is still equal to the distance d between adjacent first strip slits 101, the width a of each of the second strip slits 102 can be the same, (i.e, when the width of each of the second strip slits 102 is adjusted, the width of each of the second strip slits 102 can be reduced by the same quantitative value). Alternatively, the width of the second strip slits 102 in the same second area D can increase successively along the direction that the side area E points to the first area C (i.e., when the width of the second strip slits 102 in the same second area D is adjusted, assume that the width of the second strip slits 102 in the same second area D along the direction that the side area E points to the first area C is a₁, a₂, a₃ respectively, when a₁, a₂, a₃ are adjusted, a₁ can be reduced by 3 μm, a₂ can be reduced by 2 μm, a₃ can be reduced by 1 μm).

In specific implementations, in the above metal mask plate provided by one embodiment of the present disclosure, as shown in FIG. 2c, when the condition two and the condition three can met simultaneously, i.e., when the distance c between adjacent second strip slits 102 in the same second area D is less than the distance d between adjacent first strip slits 101, the width e of the side area E is narrowed, and the width a of the second strip slits 102 is still equal to the width b of the first strip slits 101, the distance c between adjacent second strip slits 102 in the same second area D can be the same (i.e., when the distance between adjacent second strip slits 102 in the same second area D is adjusted, the distance between adjacent second strip slits 102 in the same second area D can be reduced by the same quantitative value). Alternatively, the distance between adjacent second strip slits 102 in the same second area D can increase successively along the direction that the side area E points to the first area C. That is to say, when the distance between adjacent second strip slits 102 in the same second area D is adjusted, assume that the distance between adjacent second strip slits 102 in the same second area D along the direction that the side area E points to the first area C is c₁, c₂, c₃ respectively, when c₁, c₂, c₃ are adjusted, c₁ can be reduced by 3 μm, c₂ can be reduced by 2 μm, c₃ can be reduced by 1 μm.

In specific implementations, in the above metal mask plate provided by one embodiment of the present disclosure, as shown in FIG. 2d, when the condition one, the condition two, and the condition three are met simultaneously, i.e., the width a of the second strip slit 102 is less than the width b of the first strip slit 101, the distance c between adjacent strip slits 102 in the same second area D is less than the distance d between adjacent first strip slits 101, and the width e of the side area E is narrowed, the width a of each of the second strip slits 102 can be the same and the distance c between adjacent second strip slits 102 in the same second area D can be the same, (i.e., when the width of each of the strip slits 102 and the distance between adjacent strip slits 102 in the same second area D are adjusted, the width of each of the second strip slits 102 can be reduced by the same quantitative value and the distance between adjacent strip slits 102 in the same second area D can be reduced by the same quantitative value) Alternatively, the width a of each of the second strip slits 102 can be the same and the distance c between adjacent strip slits 102 in the same second area D can increase successively along the direction that the side area E points to the first area C. That is to say, when the width of each of the second strip slits 102 and the distance between adjacent strip slits 102 in the same second area D are adjusted, the width of each of the second strip slits 102 can be reduced by the same quantitative value, moreover, assume that the distance between adjacent strip slits 102 in the same second area D along the direction that the side area E points to the first area C is c₁, c₂, c₃ respectively, when c₁, c₂, c₃ are adjusted, c₁ can be reduced by 3 μm, c₂ can be reduced by 2 μm, c₃ can be reduced by 1 μm.

In specific implementation, in the above metal mask plate provided by one embodiment of the present disclosure, when condition one, condition two, and condition three are met simultaneously, the width a of the second strip slits 102 in the same second area D along the direction that the side area E points to the first area C may increase successively and the distance c between adjacent second strip slits 102 in the same second area D can be the same, (i.e., when the width of each of the second strip slits 102 and the distance between adjacent second strip slits 102 in the same second area D are adjusted, assume that the width of the second strip slits 102 in the same second area D along the direction that the side area E points to the first area C is a₁, a₂, a₃ respectively, when a₁, a₂, a₃ are adjusted, a₁ can be reduced by 3 μm, a₂ can be reduced by 2 μm, a₃ can be reduced by 1 μm). Moreover, the distance between adjacent second strip slits 102 in the same second area D can be reduced by the same quantitative value; or, alternatively, the width a of the second strip slits 102 in the same second area D can increase successively along the direction that the side area E points to the first area C and the distance c between adjacent second strip slits 102 in the same second area D can increase successively along the direction that the side area E points to the first area C. That is to say, when the width of each of the second strip slits 102 and the distance between adjacent second strip slits 102 in the same second area D are adjusted, assume that the width of the second strip slits 102 in the same second area D along the direction that the side area E points to the first area C is a₁, a₂, a₃ respectively, when a₁, a₂, a₃ are adjusted, a₁ can be reduced by 3 μm, a₂ can be reduced by 2 μm, a₃ can be reduced by 1 μm. Moreover, the distance between adjacent second strip slits 102 in the same second area D along the direction that the side area E points to the first area C is c₁, c₂, c₃ respectively, when c₁, c₂, c₃ are adjusted, c₁ can be reduced by 3 μm, c₂ can be reduced by 2 μm, c₃ can be reduced by 1 μm.

In specific implementation, in the above metal mask plate provided by one embodiment of the present disclosure, when the condition one is met, since the width b of the first strip slit 101 is generally 35 μm to 45 μm, when the width a of the second strip slit 102 is less than the width b of the first strip slit 101, the width a of the second strip slit 102 can be greater than 5 μm and less than 35 μm.

In specific implementations, in the above metal mask plate provided by one embodiment of the present disclosure, when the condition two is met, since the width d of the second strip slit 102 is generally 70 μm to 80.5 μm, when the distance c between adjacent second strip slits 102 in the same second area D is less than the distance d between adjacent first strip slits 101, the distance c between adjacent second strip slits 102 in the same second area D can be less than 70 μm.

In specific implementations, in the above metal mask plate provided by one embodiment of the present disclosure, when the condition three is met, since the width of the side area is generally 2.45 mm to 2.55 mm, when the width of the side area is narrowed, the width of the side area can be less than 2.45 mm.

Next, the metal mask plate provided by the embodiment of the present disclosure will be explained in detail with two specific examples.

### Example One

As shown in FIG. 2b, the width b of the first strip slit 101 of the metal mask plate is 35 μm, the distance d between adjacent first strip slits 101 is 80.5 μm, the width a of the second strip slit 102 is 25 μm, the distance c between adjacent second strip slits 102 in the same second area D is 80.5 μm, and the width e of the side area E is less than 2.45 mm.

At this time, if such designed metal mask plate is used for evaporation, then the total width of the evaporated organic substance is 60 μm smaller than the original (since 6*(35−25)=60 μm), if an organic electroluminescent display device is formed after encapsulation, the frame of the product will be reduced by 0.06 mm.

### Example Two

As shown in FIG. 2d, the width b of the first strip slit 101 of the metal mask plate is 35 μm, the distance d between adjacent first strip slits 101 is 80.5 μm, the width a of the second strip slit 102 is less than 35 μm, the distance c between adjacent second strip slits 102 in the same second area D is less than 80.5 μm, and the width e of the side area E is less than 2.45 mm.

As shown in FIG. 3a and FIG. 3b, such designed metal mask plate is combined with a magnetic separator 104, in the process of moving upwards being adsorbed by the magnetic separator 104, assume that three second strip slits 102 parallel to the first strip slits 101 are arranged in each second area D, the areas between adjacent second strip slits 102 are R₁, R₂, R₃ respectively, and the broken line is set as the central force line of the area between adjacent second strip slits 102. As for R₃, the right side suffers the interaction force F₃ given by the side area E, and the interaction force FD₂₃ given by R₂, and the left side suffers the interaction force FS₁ given by the area between adjacent first strip slits 101 close to R₃. As for R₂, the right side suffers the interaction force F₂ given by the side area E, and the interaction force FD12 given by R₁, and the left side suffers the interaction force FD₂₃ given by R₃. As for R₁, the right side suffers the interaction force F₁ given by the side area E, the left side suffers the interaction force FD₁₂ given by R₂. When the width e of the side area E is narrowed, the interaction forces to R₁, R₂, R₃ will be diminished, i.e., F₁, F₂, F₃ will be diminished, when the distance c between adjacent second strip slits 102 in the same second area D can increase successively along the direction that the side area E points to the first area C, (i.e., R₁<R₂<R₃), the interaction forces generated between R₁ and R₂, R₂ and R₃ will be diminished, so as for the force suffered by R₃, the sum of the forces F₃ and FD₂₃ at the right side of R₃ will be diminished (compared with the previous total force when there is no change). However, when the width a of the second strip slit 102 is diminished, the side area E will approach inwards, such that the interaction force between the side area E and R₃ will be increased, although the interaction force between the side area E and R₃ is increased, in the case of not considering that the width a of the second strip slit 102 is diminished, the sum of F₃ and FD₂₃ is diminished, which leaves allowance for increase of F₃ later, so that the force balance at two sides of R₃ becomes possible, thereby R₃ will not be deformed. In the case of not being deformed, the width a of the second strip slit 102 is narrowed, the distance c between adjacent second strip slits 102 in the same second area D is also reduced correspondingly. Finally, the outmost two second strip slits are made to be close to the effective display area, if such a metal mask plate is used for evaporation, the manufactured device will form the narrow frame effect.

Based on the same inventive concept, another embodiment of the present disclosure further provides an organic electroluminescent display device manufactured using the above metal mask plate provided by one embodiment of the present disclosure.

The embodiment of the present disclosure provides a metal mask plate and an organic electroluminescent display device manufactured using the same, the metal mask plate comprising: a substrate, a first area arranged on the substrate for forming display images and second areas located at left and right sides of the first area respectively. The first area may be provided with a plurality of first strip slits extending along the column direction and being parallel to each other with equal intervals, each of the second areas being provided with at least three second strip slits parallel to the first strip slits. At least two of the following three conditions must be met: condition one: a width of the second strip slit is less than a width of the first strip slit; condition two: a distance between adjacent second strip slits in a same second area is less than a distance between adjacent first strip slits; and/or condition three: a width of a side area is narrowed, the side area being an area between the second strip slit in the second area closest to a side frame of the metal mask plate and the side frame, the side frame being a frame parallel to the extending direction of the second strip slit. By adjusting the width of the second strip slit, the distance between adjacent second strip slits in the same second area and the width of the side area, when at least two of the above conditions are met, and on the basis that the first strip slits in the first area would not be deformed, relative to the prior art, not only the influence of the magnetic field to the second strip slits can be released, but also the second areas can be made to occupy a relatively small area, so as to realize narrow frame in space.

Based on the present disclosure, a skilled person having ordinary skill in the art can make various modifications and variations to the present disclosure without departing from the spirit and scope of the present disclosure. In this way, provided that these modifications and variations of the present disclosure belong to the scope of the claims of the present disclosure and the equivalent technologies thereof, the present disclosure would also intend to cover these modifications and variations.

1-11. (canceled)

12. A metal mask plate, comprising:
a substrate with a first area arranged on the substrate for forming display images and two second areas located at left and right sides of the first area respectively; wherein the first area includes a plurality of first strip slits extending along a column direction and parallel to each other with equal intervals, and wherein each of the second areas includes at least three second strip slits parallel to the first strip slits; wherein,
at least two of the following three conditions are met:
condition one: a width of the second strip slit is less than a width of the first strip slit;
condition two: a distance between adjacent second strip slits in a same second area is less than a distance between adjacent first strip slits; and
condition three: a width of a side area is narrowed, the side area being an area between the second strip slit in the second area closest to a side frame of the metal mask plate and the side frame, the side frame being a frame parallel to the extending direction of the second strip slit.

13. The metal mask plate as claimed in claim 12, wherein when the condition one and the condition two are met simultaneously, the width of each of the second strip slits is the same.

14. The metal mask plate as claimed in claim 13, wherein the distance between adjacent second strip slits in the same second area is the same, increases successively along a direction that the side area points to the first area, or decreases successively along a direction that the side area points to the first area.

15. The metal mask plate as claimed in claim 12, wherein when the condition one and the condition three are met simultaneously, the width of each of the second strip slits is the same or increases successively along a direction that the side area points to the first area.

16. The metal mask plate as claimed in claim 12, wherein when the condition two and the condition three are met simultaneously, the distance between adjacent second strip slits in the same second area is the same or increases successively along a direction that the side area points to the first area.

17. The metal mask plate as claimed in claim 12, wherein when the condition one, the condition two and the condition three are met simultaneously, the width of each of the second strip slits is the same; and
the distance between adjacent second strip slits in the same second area is the same or increases successively along a direction that the side area points to the first area.

18. The metal mask plate as claimed in claim 12, wherein when the condition one, the condition two, and the condition three are met simultaneously, the width of the second strip slits in the same second area increases successively along a direction that the side area points to the first area; and
the distance between adjacent second strip slits in the same second area is the same or increases successively along the direction that the side area points to the first area.

19. The metal mask plate as claimed claim 12, wherein when the condition one is met, the width of the second strip slit is greater than 5 μm and less than 35 μm.

20. The metal mask plate as claimed claim 13, wherein when the condition one is met, the width of the second strip slit is greater than 5 μm and less than 35 μm.

21. The metal mask plate as claimed in claim 3, wherein when the condition one is met, the width of the second strip slit is greater than 5 μm and less than 35 μm.

22. The metal mask plate as claimed in claim 15, wherein when the condition one is met, the width of the second strip slit is greater than 5 μm and less than 35 μm.

23. The metal mask plate as claimed in claim 16, wherein when the condition one is met, the width of the second strip slit is greater than 5 μm and less than 35 μm.

24. The metal mask plate as claimed in claim 17, wherein when the condition one is met, the width of the second strip slit is greater than 5 μm and less than 35 μm.

25. The metal mask plate as claimed in claim 18, wherein when the condition one is met, the width of the second strip slit is greater than 5 μm and less than 35 μm.

26. The metal mask plate as claimed in claim 12, wherein when the condition two is met, the distance between adjacent second strip slits in the same second area is less than 70 μm.

27. The metal mask plate as claimed in claim 13, wherein when the condition two is met, the distance between adjacent second strip slits in the same second area is less than 70 μm.

28. The metal mask plate as claimed in claim 14, wherein when the condition two is met, the distance between adjacent second strip slits in the same second area is less than 70 μm.

29. The metal mask plate as claimed in claim 12, wherein when the condition three is met, the width of the side area is less than 2.45 mm.

30. The metal mask plate as claimed in claim 13, wherein when the condition three is met, the width of the side area is less than 2.45 mm.

31. An organic electroluminescent display device manufactured using the metal mask plate as claimed in claim 12.
